(19) United States
(12) Patent Application Publication
(10) Pub. No.: US 2014/0117974 A1
(43) Pub. Date: May 1, 2014

(54) RSSI CIRCUIT WITH LOW VOLTAGE AND WIDE DETECTABLE POWER RANGE

(71) Applicant: KEYSTONE SEMICONDUCTOR CORP., HSINCHU (TW)

(72) Inventors: Chung-Yun Chou, HSINCHU (TW); Chao-Tung Yang, HSINCHU (TW)

(73) Assignee: KEYSTONE SEMICONDUCTOR CORP., HSINCHU (TW)

(21) Appl. No.: 13/663,680

(22) Filed: Oct. 30, 2012

(51) Int. Cl. G01R 29/10

(52) U.S. Cl. 324/123 R

(57) ABSTRACT

An RSSI circuit with low voltage and wide detectable power range is provided, including a plurality of amplifiers connected in a cascade manner; a plurality of rectifiers, each of the plurality of rectifier having an input connected to an output of each of the plurality of amplifiers in turn; and a selector, connected to an output of each of the plurality of rectifiers for selecting an output among the outputs from the plurality of rectifiers. By using selector to select an output among outputs of the rectifiers, the RSSI circuit of the present invention can detect a wider power range with same voltage range because each stage can utilize the full voltage range.

### FIELD OF THE INVENTION

The present invention generally relates to a received signal strength indicator (RSSI) circuit, and more specifically to an RSSI circuit with low voltage and wide detectable power range.

### BACKGROUND OF THE INVENTION

Received signal strength indicator (RSSI) is a metric for measuring the power present in a received radio signal, i.e., the strength of the signal. The general design is to pick RF signals or intermediate frequency (IF) signals and generate a voltage or current output equivalent to the signal strength. The ability of the receiver to pick the weakest signal is referred to as receiver sensitivity, which is the higher, the better. The signal strength can be measured based on output voltage. In telecommunication, RSSI is often performed in intermediate frequency (IF) stage after the amplification for the reasons of design. RSSI output is often a DC analog level, which can be sampled by an internal ADC. RSSI is usually invisible to the user of the device containing the radio receiver employing RSSI, such as a mobile phone, wireless network adaptor or remote control.

In general, RSSI circuit is realized with multi-stage amplifiers and rectifiers. FIG. 1 shows a schematic view of a conventional RSSI circuit. The RSSI circuit is implemented with five amplifiers and the same number of rectifiers arranged in a five-stage structure. As shown in FIG. 1, amplifiers 101 are arranged in cascade manner, with output from each of amplifiers 101 connected to input of a respective rectifier 102. The outputs of rectifiers 102 are summed to obtain the final output for the RSSI circuit.

FIG. 2 shows a diagram illustrating the final output of RSSI circuit of FIG. 1. The diagram shows the RSSI output voltage versus the power strength at the detected point. The headroom range indicated along the output voltage axis is the range wherein the RSSI output voltage can grow into. As shown in FIG. 2, because the final output is a summation of each stage, the five-stage implementation of RSSI in FIG. 1 results in a line corresponding to five segments tandem linked, with each segment representing output of each stage. The slope of the line in FIG. 2 can be interpreted as the sensitivity of the RSSI, or the capability to discriminate the power strength in the input signals. In other words, an interval indicating the input power range is mapped to a voltage interval. Because the entire range of the input power is to be mapped to the entire allowable voltage range, i.e., the voltage headroom indicated in FIG. 2, a fixed input power interval can only be mapped to a relatively small voltage interval and may be misjudged for interfering with noise. In other words, the detectable power range is usually restricted. To increase the detectable power range, the voltage must be high to provide sufficient voltage headroom for RSSI to operate in, and will be limited in the low supply voltage operation.

### SUMMARY OF THE INVENTION

The present invention has been made to overcome the aforementioned drawback of conventional RSSI circuit. The primary object of the present invention is to provide an RSSI circuit that is able to extend detectable power range without raise the voltage requirement.

Another object of the present invention is provide an RSSI circuit with higher sensitivity and able to enlarge the output voltage to discriminate a slight detected power interval.

To achieve the aforementioned objects, the present invention provides an RSSI circuit with low voltage and wide detectable power range, including a plurality of amplifiers connected in a cascade manner; a plurality of rectifiers, each of the plurality of rectifier having an input connected to an output of each of the plurality of amplifiers in turn; and a selector, connected to an output of each of the plurality of rectifiers for selecting an output among the outputs from the plurality of rectifiers.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional RSSI circuit;

FIG. 2 shows a diagram illustrating the final output of RSSI circuit of FIG. 1;

FIG. 3 shows a schematic view of an embodiment of RSSI circuit according to the present invention; and

FIG. 4 shows a diagram illustrating the output of RSSI of FIG. 3.

### DETAILED DESCRIPTION OF THE PREFERRED EMBODIMENTS

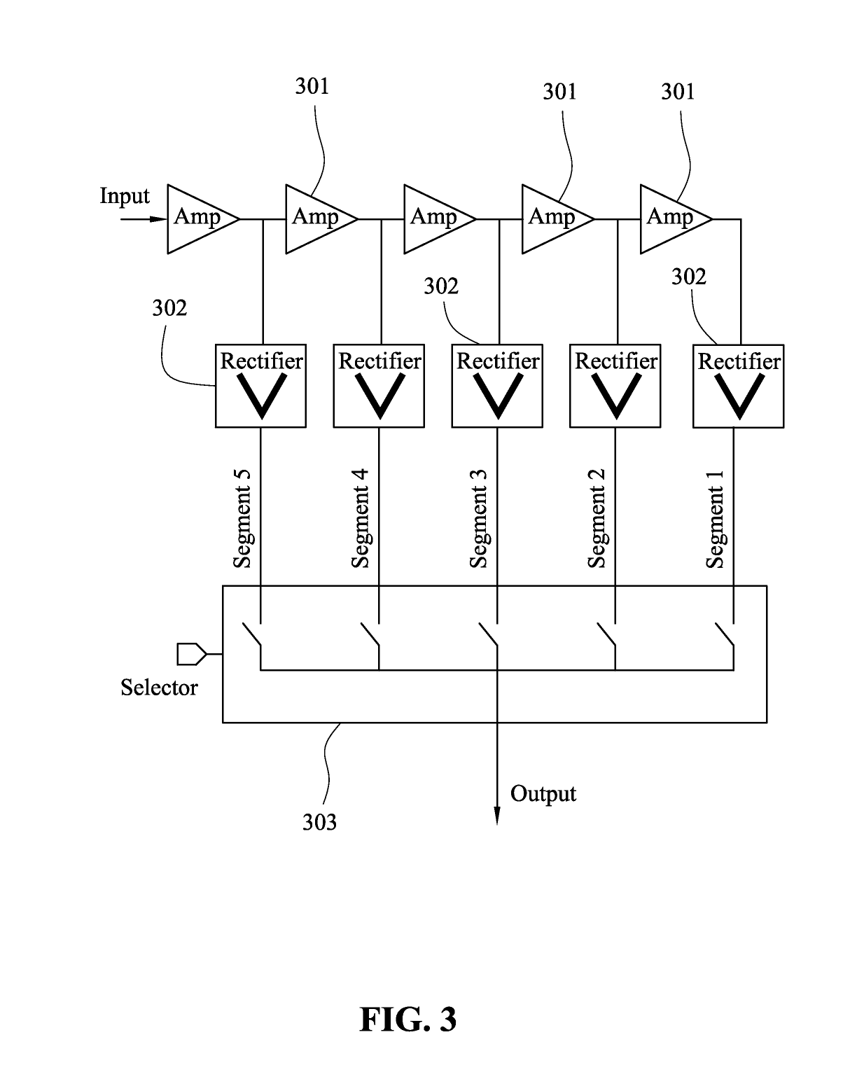

FIG. 3 shows a schematic view of an embodiment of RSSI circuit according to the invention. As shown in FIG. 3, an RSSI circuit of the present invention includes a plurality of amplifiers 301 connected in a cascade manner; a plurality of rectifiers 302, each of the plurality of rectifier 302 having an input connected to an output of each of the plurality of amplifiers 301 in turn; and a selector 303, connected to an output of each of the plurality of rectifiers 302 for selecting an output among the outputs from the plurality of rectifiers 302. In this embodiment, five amplifiers 301 and five rectifiers 302 are included to implement the five-stage RSSI circuit. Different number of stages can also be used.

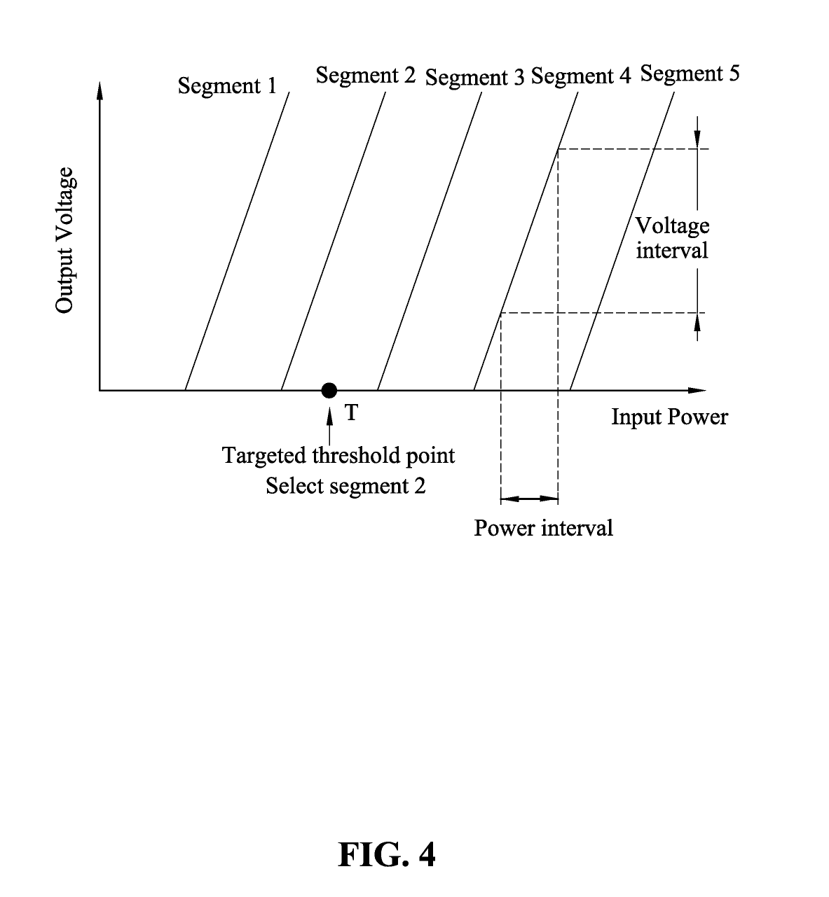

FIG. 4 shows a diagram illustrating the output of RSSI of FIG. 3. Because selector 303 is used to select one output among all the outputs of entire RSSI circuit, i.e., the five outputs in this embodiment, the mapping of input power range to the output voltage range shows the five parallel segments, with each mapping segment corresponding to a stage, i.e., an output from a rectifier 302.

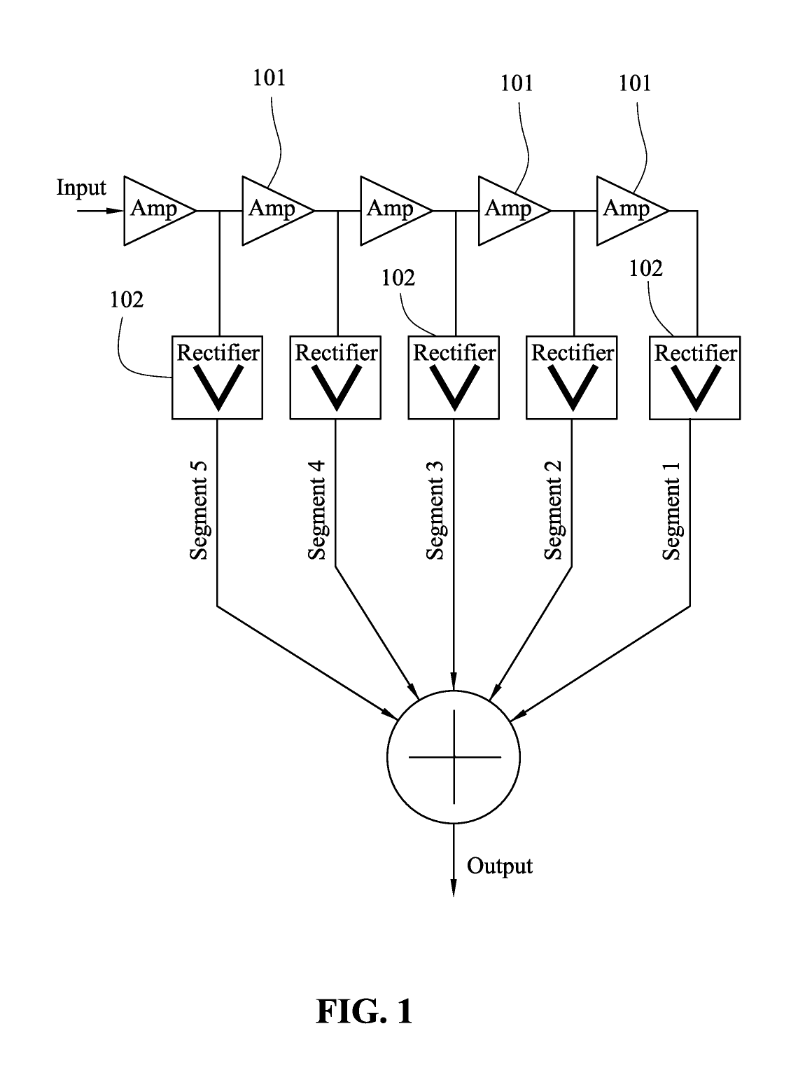

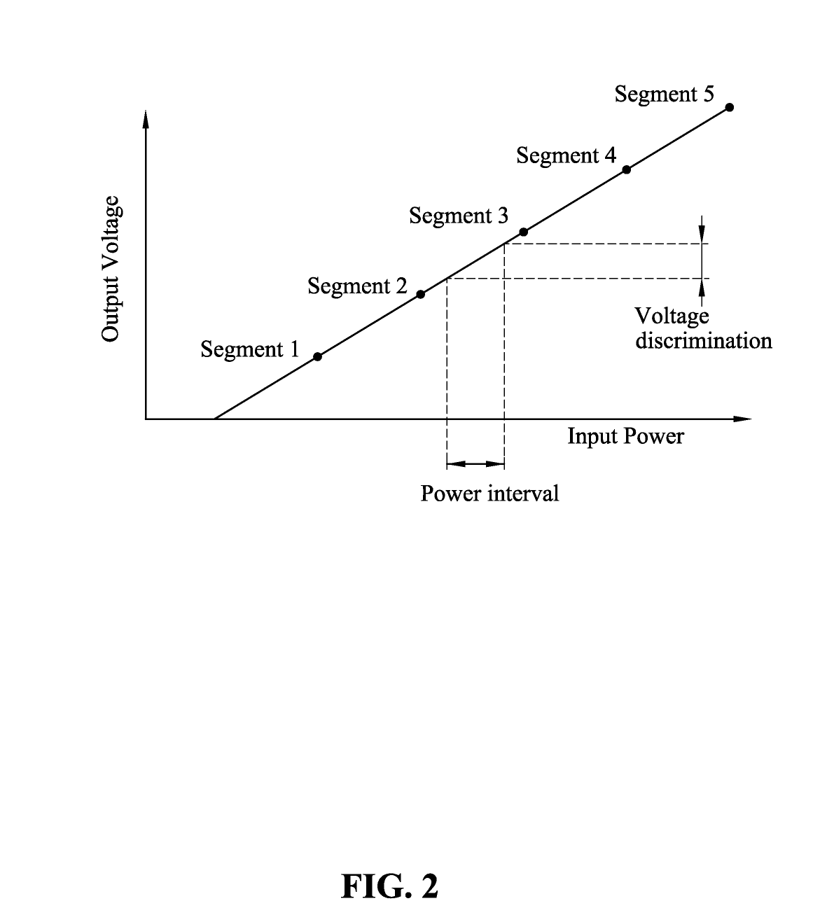

Compared to the mapping diagram of input power range to the output voltage range shown in FIG. 2, a fixed input power interval in FIG. 4 is mapped to a much larger voltage interval. In other words, the RSSI circuit of the present invention provides higher discriminating capability for a fixed detected power interval, and the overall RSSI circuit can detect a wider range of input power than the conventional RSSI circuit of FIG. 1.

It is worth noting that the present invention also allow selectable mapping segment. Each power interval can be seen as a window bounded by an upper threshold and a lower threshold. For a target input power within the window, an appropriate mapping segment can be selected. As in indicated in FIG. 4, for a target threshold T, selector 303 can be set to select corresponding segment 2 for mapping input power to an output voltage.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An RSSI circuit with low voltage and wide detectable power range, comprising:
a plurality of amplifiers connected in a cascade manner;
a plurality of rectifiers, each of said plurality of rectifiers having an input connected to an output of each of said plurality of amplifiers in turn; and
a selector, connected to an output of each of said plurality of rectifiers for selecting an output among said outputs from said plurality of rectifiers.

2. The RSSI circuit as claimed in claim 1, wherein said selector selects said output according to a target detectable input power.
